(19) United States
(12) Patent Application Publication
(10) Pub. No.: US 2026/0136488 A1
(43) Pub. Date: May 14, 2026

(54) DRIVING MECHANISM

(71) Applicant: TDK TAIWAN CORP., Taoyuan City (TW)

(72) Inventors: Chia-Che WU, Taoyuan City (TW); Yi-Ho CHEN, Taoyuan City (TW)

(21) Appl. No.: 19/382,974

(22) Filed: Nov. 7, 2025

Related U.S. Application Data
(60) Provisional application No. 63/718,141, filed on Nov. 8, 2024.

(51) Int. Cl. H05K 7/20; F04D 25/08; H02K 3/26; H02K 33/18

(52) U.S. Cl. CPC H05K 7/20172; F04D 25/08; H02K 3/26; H02K 33/18; H02K 2203/03

(57) ABSTRACT

A driving mechanism is provided, including a fixed part, a movable part, and a driving assembly. The movable part is connected to the fixed part, and the driving assembly is configured for moving the movable part relative to the fixed part. The driving assembly includes a first driving element and a second driving element, wherein the first driving element is disposed on the movable part, and the second driving element is disposed on the fixed part and located adjacent to the first driving element.

### CROSS REFERENCE TO RELATED APPLICATIONS

This application claims the benefit of U.S. Provisional Application No. 63/718,141, filed Nov. 8, 2024, the entirety of which is incorporated by reference herein.

### BACKGROUND OF THE INVENTION

### Field of the Invention

The present invention relates to a driving mechanism, and, in particular, to a driving mechanism having a fan structure.

### Description of the Related Art

As technology has advanced, a lot of electronic devices (for example, laptop computers and smartphones) have incorporated the functionality of taking photographs and recording video. These electronic devices have become increasingly commonplace, and have been developed to be more convenient and thin. More and more options are provided for users to choose from.

However, integrated circuits (ICs) and other components inside an electronic device may generate heat, which can lead to reduced performance, lower efficiency, and a decreased lifespan. Therefore, addressing the aforementioned problems has become a challenge.

### BRIEF SUMMARY OF THE INVENTION

An embodiment of the present invention provides a driving mechanism that includes a fixed part, a movable part, and a driving assembly. The movable part is connected to the fixed part, and the driving assembly is configured to move the movable part relative to the fixed part.

In some embodiments, the driving assembly includes a first driving element and a second driving element, and the movable part has a main body and a vibrating portion connected to the main body. The first driving element is disposed on the first surface of the vibrating portion, and the second driving element is disposed on the fixed part and located adjacent to the first driving element.

### BRIEF DESCRIPTION OF THE DRAWINGS

The present invention can be more fully understood by reading the subsequent detailed description and examples with references made to the accompanying drawings, wherein:

FIG. 1 and FIG. 2 show exploded views of a driving mechanism 100 in accordance with an embodiment of the invention.

FIG. 3 shows a cross-sectional view of the first driving element M formed on the vibrating portion P12 of the movable part P1.

FIGS. 4-6 are perspective diagrams of the driving mechanism 100 in FIGS. 1 and 2 after assembly.

FIG. 7 is a cross-sectional view of the driving mechanism 100 when a first periodic current signal is applied to the coils C1 in the upper and lower portions B11 and B12 of the second driving element B1.

FIG. 8A is a perspective diagram of the driving mechanism 100 when a second periodic current signal is applied to the coils C1 in the upper and lower portions B11 and B12 of the second driving element B1.

FIG. 8B is a side view of the driving mechanism 100 when a second periodic current signal is applied to the coils C1 in the upper and lower portions B11 and B12 of the second driving element B1.

FIG. 9 and FIG. 10 show exploded views of a driving mechanism 200 in accordance with another embodiment of the invention.

FIG. 11 shows a cross-sectional view of the driving mechanism 200 when a first periodic current signal is applied to the coils C2 in the upper and lower portions B21 and B22 of the second driving element B2.

FIG. 12 is a perspective diagram of the driving mechanism 200 when a second periodic current signal is applied to the coils C2 in the upper and lower portions B21 and B22 of the second driving element B2.

FIG. 13 shows a side view of the driving mechanism 200 when a second periodic current signal is applied to the coils C2 in the upper and lower portions B21 and B22 of the second driving element B2.

FIG. 14 shows an exploded view of a driving mechanism 300 in accordance with another embodiment of the invention.

FIG. 15 is a perspective diagram of the driving mechanism 300 in FIG. 14 after assembly.

FIG. 16 is a schematic diagram of the movable part P3 in FIGS. 14 and 15.

FIG. 17 shows a cross-sectional view of the driving mechanism 300 when a first periodic current signal is applied to the second driving element C3 formed on or embedded in the vibrating portion P32 of the movable part P3.

FIG. 18 is a perspective diagram of the driving mechanism 300 when a second periodic current signal is applied to the second driving element C3 formed on or embedded in the vibrating portion P32 of the movable part P3.

FIG. 19 shows a side view of the driving mechanism 300 when a second periodic current signal is applied to the second driving element C3 formed on or embedded in the vibrating portion P32 of the movable part P3.

### DETAILED DESCRIPTION OF THE INVENTION

The making and using of the embodiments of the driving mechanism are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

In the following detailed description of the preferred embodiments, reference is made to the accompanying drawings, and in which specific embodiments of which the invention may be practiced are shown by way of illustration. In this regard, directional terminology, such as “top,” “bottom,” “left,” “right,” “front,” “back,” etc., is used with reference to the orientation of the figures being described. The components of the present invention can be positioned in a number of different orientations. As such, the directional terminology is used for the purposes of illustration and is in no way limiting.

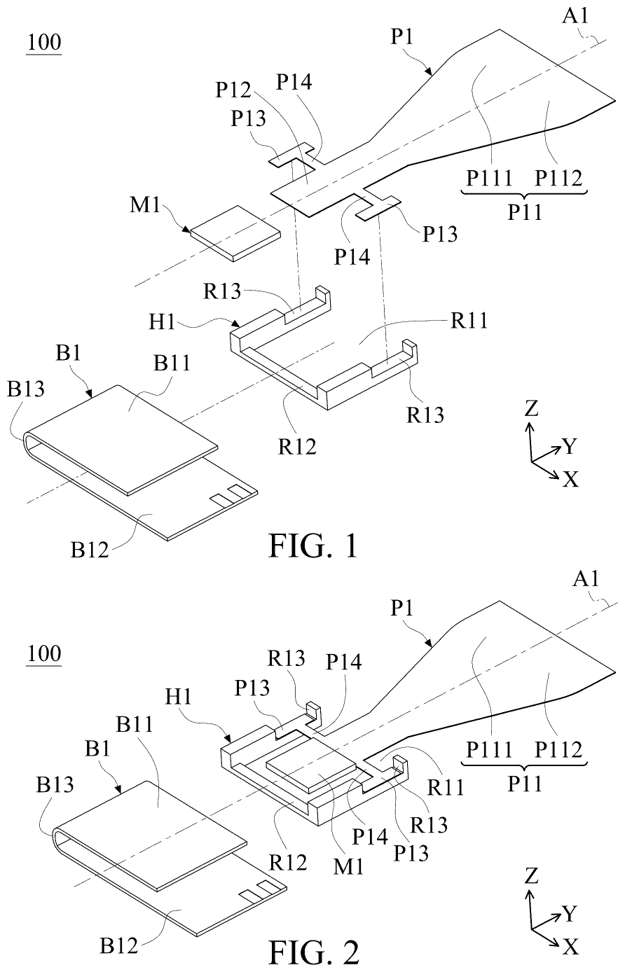

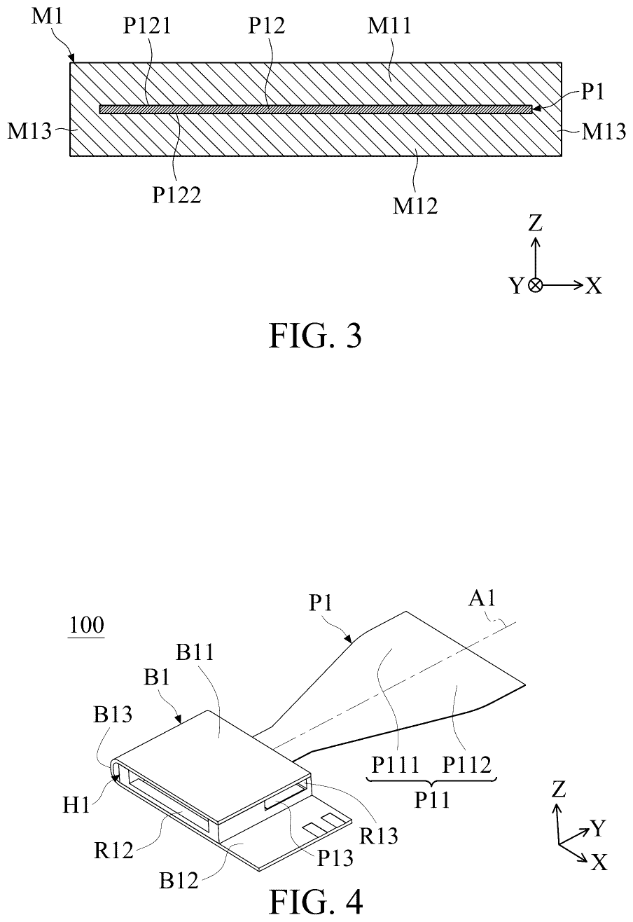

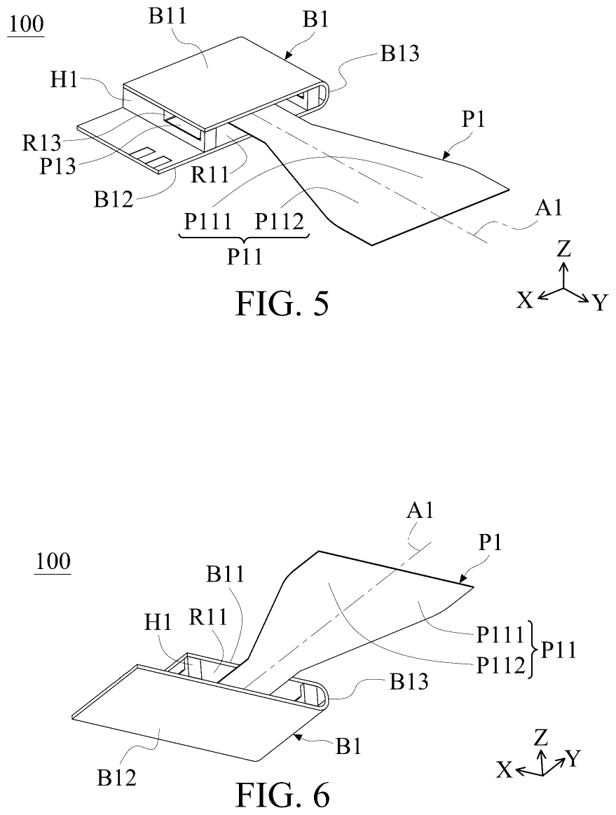

FIG. 1 and FIG. 2 show exploded views of a driving mechanism 100 in accordance with an embodiment of the invention. FIG. 3 shows a cross-sectional view of the first driving element M formed on the vibrating portion P12 of the movable part P1. FIGS. 4-6 are perspective diagrams of the driving mechanism 100 in FIGS. 1 and 2 after assembly.

Referring to FIGS. 1-6, the driving mechanism 100 may be disposed in a thin electronic device for driving the movable part P1 (e.g. a fan) to swing and dissipate heat from the electronic device. In this embodiment, the driving mechanism 100 primarily comprises a fixed part H1, a movable part P1 connected to the fixed part H1, a first driving element M1 disposed on the movable part P1, and a second driving element B1 disposed on the fixed part H1. The first driving element M1 may comprise magnetic material (e.g. a permanent magnet or magnetic permeable material), and the second driving element B1 may be an FPC with at least a coil (e.g. a planar coil) embedded therein. The first and second driving elements M1 and B1 constitute a driving assembly for moving the movable part P1 relative to the fixed part H1.

As shown in FIGS. 1-2, the fixed part H1 has a C-shaped frame that forms a first opening R11, a second opening R12, and two recesses R13. The movable part P1 may comprise a metal sheet or a polyimide (PI) sheet that has a flat and thin structure. Specifically, the movable part P1 comprises a main body P11, a vibrating portion P12, two support portions P13, and two bridge portions P14. The vibrating portion P12 is connected to the main body P11 and encompassed by the first driving element M1.

In this embodiment, the main body P11 of the movable part P1 has a symmetrical structure that includes a first flexible portion P111 and a second flexible portion P112 arranged along the X axis (first axis) which is perpendicular to the central axis A1 of the movable part P1. The first and second flexible portions P111 and P112 are symmetrical with respect to the central axis A1, and the central axis A1 is parallel to the Y axis.

It can be seen in FIGS. 1-6 that the support portions P13 are affixed in the recesses R13 of the fixed part H1, and the bridge portions R14 are connected between the support portions P13 and the main body P11. Specifically, the support portion P13 and the bridge portion P14 form a T-shaped resilient structure. When the movable part P1 is driven to move, the bridge portions R14 may twist so that the main body P11 of the movable part P1 can swing to dissipate heat from the electronic device.

Moreover, as can be seen in FIG. 3, the vibrating portion P12 is encompassed by the first driving element M1. The first driving element M1 has a first portion M11 disposed on the first surface P121 of the vibrating portion P12, wherein the first surface P121 is parallel to the central axis Aland the X axis (first axis).

Additionally, the first driving element M1 has a second portion M12 disposed on a second surface P122 of the vibrating portion P12, wherein the first and second surfaces P121 and P 122 are located on opposite sides of the vibrating portion P12. Moreover, the first driving element M1 further has two third portions M13 connected between the first and second portions M11 and M12. It should be noted that the third portions M13 and the vibrating portion P12 do not overlap when viewed in the Z direction that is perpendicular to the first surface P121.

In this embodiment, the first driving element M1 may be formed on the vibrating portion P12 by plating. The thickness of the movable part P1 is substantially 0.03 mm, the thickness of the first and second portions M11 and M12 is substantially equal to or greater than 0.38 mm.

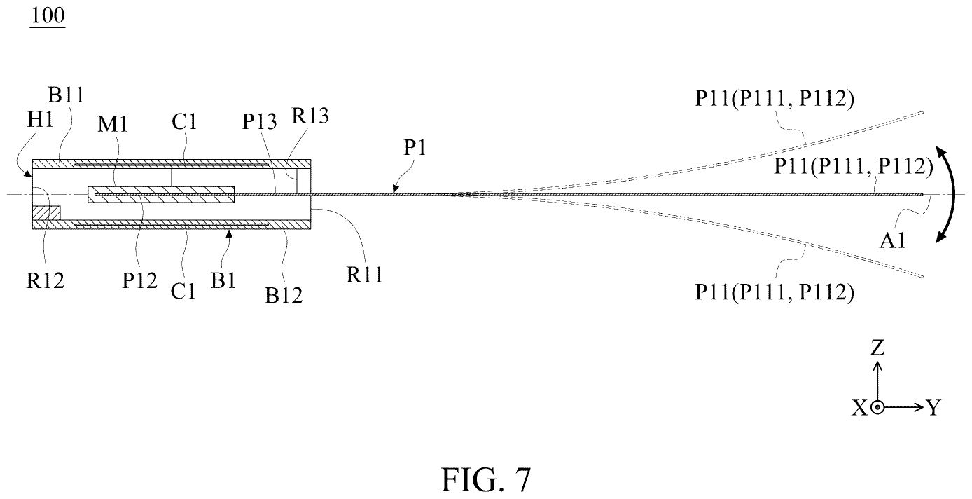

FIG. 7 is a cross-sectional view of the driving mechanism 100 when a first periodic current signal is applied to the coils C1 in the upper and lower portions B11 and B12 of the second driving element B1.

Referring to FIGS. 1-7, the second driving element B1 (e.g. FPC) has an upper portion B11, a lower portion B12 and a foldable portion B13 connected between the upper and lower portions B11 and B12. The upper and lower portions B11 and B12 are parallel to each other, and the first and second openings R11 and R12 of the fixed part H1 are located between the upper and lower portions B11 and B12. Specifically, two coils C1 are disposed in the upper and lower portions B11 and B12 and located adjacent to the first driving element M1 (e.g. a permanent magnet or magnetic permeable material).

It should be noted that the first driving element M1 and the coils C1 do not overlap when viewed along the central axis A1. In this embodiment, the first driving element M1 is located between the two coils C1 along the Z axis.

Moreover, as can be seen in FIG. 7, the central axis A1 of the movable part P1 extends through the first and second openings R11 and R12 of the fixed part H1. When a first periodic signal is applied to the coils C1, the first driving element M1 and the vibrating portion P12 are driven to vibrate, whereby the main body P11 of the movable part P1 can swing in a first mode and generate an air flow to dissipate heat from the electronic device. In this embodiment, the frequency of the first periodic signal is close to one of the resonance frequencies of the movable part P1. When the main body P11 of the movable part P1 swings in the first mode and viewed along the X axis (first axis), the first and second flexible portions P111 and P112 substantially overlap (FIG. 7).

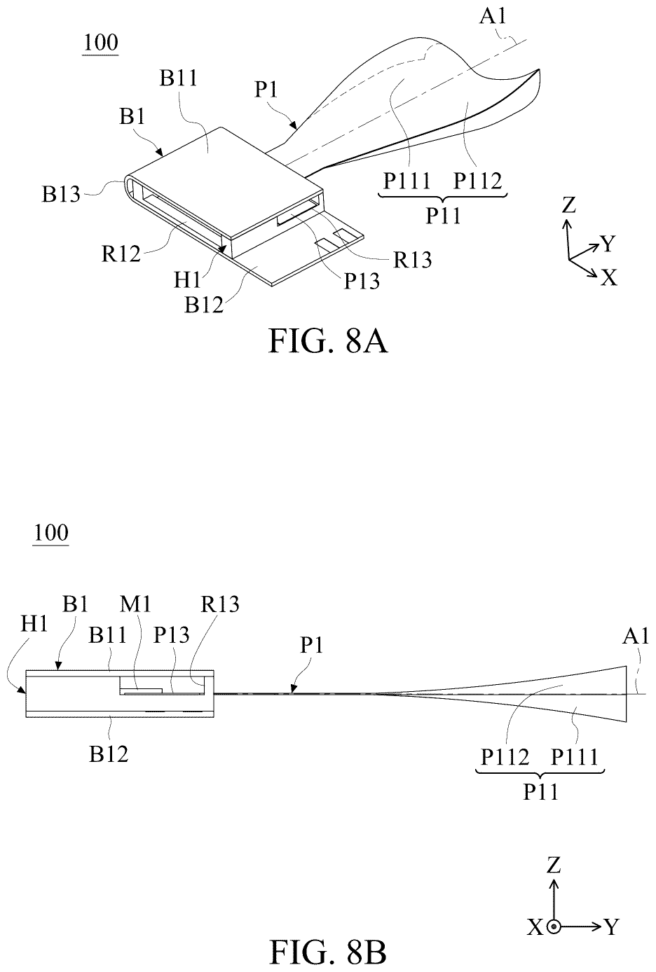

FIG. 8A is a perspective diagram of the driving mechanism 100 when a second periodic current signal is applied to the coils C1 in the upper and lower portions B11 and B12 of the second driving element B1. FIG. 8B is a side view of the driving mechanism 100 when a second periodic current signal is applied to the coils C1 in the upper and lower portions B11 and B12 of the second driving element B1.

Referring to FIGS. 8A and 8B, when a second periodic signal is applied to the coils C1 in the upper and lower portions B11 and B12 of the second driving element B1, the main body P11 of the movable part P1 can be driven to swing in a second mode, thereby generating an air flow to dissipate heat from the electronic device.

Specifically, when the main body P11 of the movable part P1 swings in the second mode and viewed along the X axis (first axis), as shown in FIGS. 8A and 8B, the main body P11 of the movable part P1 twists and the first and second flexible portions P111 and P112 do not overlap. In this embodiment, the frequency of the second periodic signal is close to a different resonance frequency of the movable part P1, thereby improving the flexibility and efficiency of the driving mechanism 100.

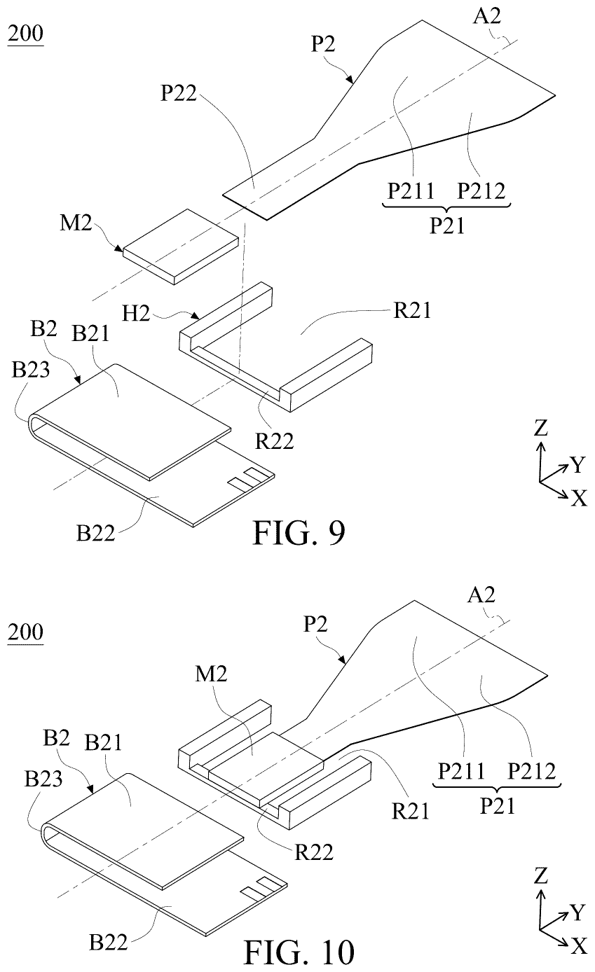

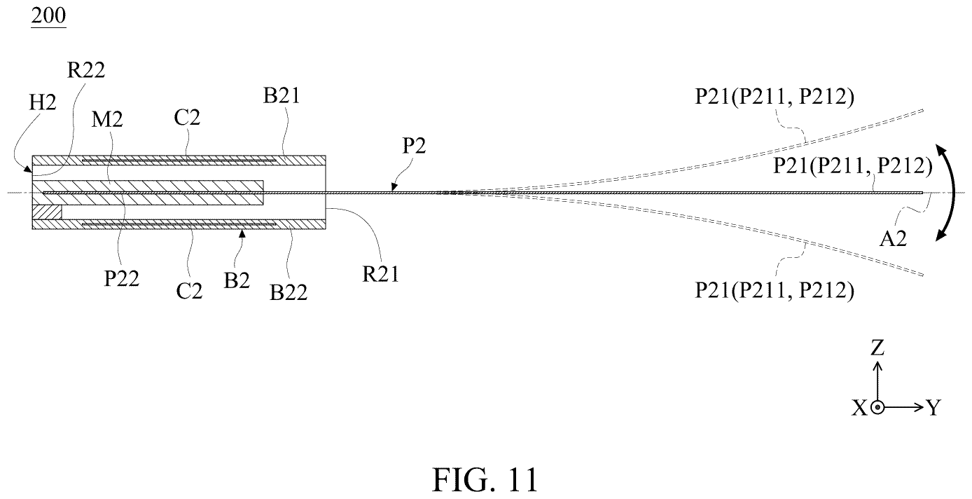

FIG. 9 and FIG. 10 show exploded views of a driving mechanism 200 in accordance with another embodiment of the invention. FIG. 11 shows a cross-sectional view of the driving mechanism 200 when a first periodic current signal is applied to the coils C2 in the upper and lower portions B21 and B22 of the second driving element B2.

Referring to FIGS. 9-11, the driving mechanism 100 may be disposed in an electronic device for driving the movable part P2 (e.g. a fan) to swing and dissipate heat from the electronic device. In this embodiment, the driving mechanism 200 primarily comprises a fixed part H2, a movable part P2 connected to the fixed part H2, a first driving element M2 disposed on the movable part P2, and a second driving element B2 disposed on the fixed part H2. The first driving element M2 may comprise magnetic material (e.g. a permanent magnet or magnetic permeable material), and the second driving element B2 may be an FPC with at least a coil (e.g. a planar coil) embedded therein. The first and second driving elements M2 and B2 constitute a driving assembly for moving the movable part P2 relative to the fixed part H2.

The fixed part H2 has a C-shaped frame that forms a first opening R21 and a second opening R22. The movable part P2 may comprise a metal sheet or a polyimide (PI) sheet that has a flat and thin structure. Specifically, the movable part P2 has a main body P21 and a vibrating portion P22 arranged along the central axis A2. The vibrating portion P22 is connected to the main body P21 and encompassed by the first driving element M2.

In this embodiment, the main body P21 of the movable part P2 has a symmetrical structure that includes a first flexible portion P211 and a second flexible portion P212 arranged along the X axis (first axis) which is perpendicular to the central axis A2 of the movable part P2. The first and second flexible portions P211 and P212 are symmetrical with respect to the central axis A2, and the central axis A2 is parallel to the Y axis.

It can be seen in FIGS. 9-11 that the vibrating portion P22 is encompassed by the first driving element M2. The end of the first driving element M2 and the vibrating portion P22 are adhered to the fixed part H2 and received in the second opening R22 (FIG. 11). In this embodiment, the first driving element M2 may be formed on the vibrating portion P22 by plating.

The second driving element B2 (e.g. FPC) has an upper portion B21, a lower portion B22 and a foldable portion B23 connected between the upper and lower portions B21 and B22. The upper and lower portions B21 and B22 are parallel to each other, and the first and second openings R21 and R22 of the fixed part H2 are located between the upper and lower portions B11 and B22. Specifically, two coils C2 are disposed in the upper and lower portions B21 and B22 and located adjacent to the first driving element M2 (e.g. a permanent magnet or magnetic permeable material).

It should be noted that the first driving element M2 and the coils C2 do not overlap when viewed along the central axis A2. In this embodiment, the first driving element M2 is located between the two coils C2 along the Z axis.

As can be seen in FIG. 11, the central axis A2 of the movable part P2 extends through the first and second openings R21 and R22 of the fixed part H2. When a first periodic signal is applied to the coils C2, the first driving element M2 and the vibrating portion P22 are driven to vibrate, whereby the main body P21 of the movable part P2 can swing in a first mode and generate an air flow to dissipate heat from the electronic device. In this embodiment, the frequency of the first periodic signal is close to one of the resonance frequencies of the movable part P2. Specifically, when the main body P21 of the movable part P2 swings in the first mode and viewed along the X axis (first axis), the first and second flexible portions P211 and P212 substantially overlap (FIG. 11).

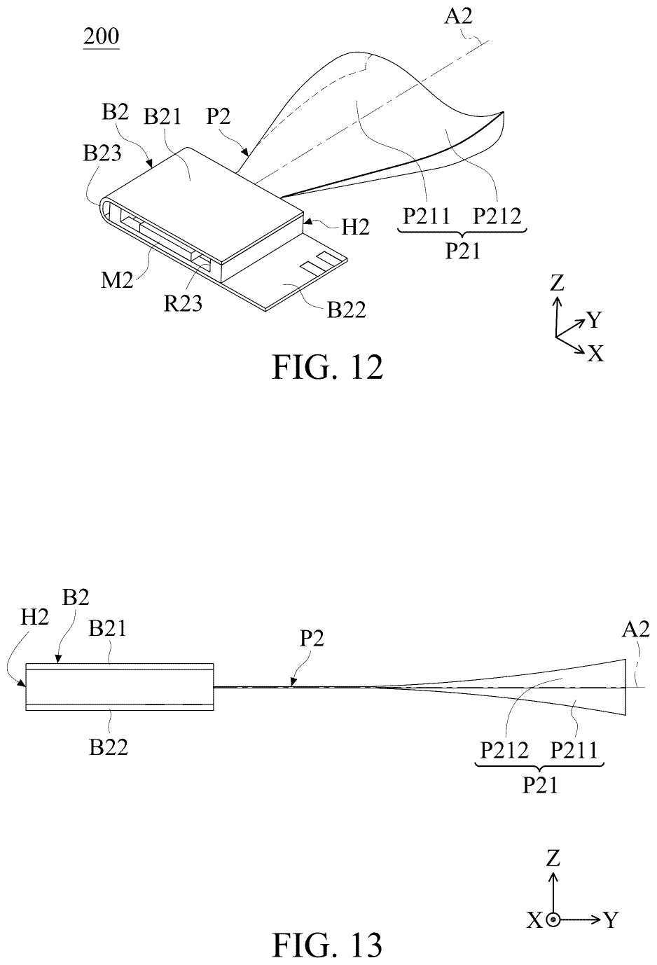

FIG. 12 is a perspective diagram of the driving mechanism 200 when a second periodic current signal is applied to the coils C2 in the upper and lower portions B21 and B22 of the second driving element B2. FIG. 13 shows a side view of the driving mechanism 200 when a second periodic current signal is applied to the coils C2 in the upper and lower portions B21 and B22 of the second driving element B2.

Referring to FIGS. 12 and 13, when a second periodic signal is applied to the coils C2 in the upper and lower portions B21 and B22 of the second driving element B12, the main body P21 of the movable part P2 is driven to swing in a second mode, thereby generating an air flow to dissipate heat from the electronic device.

Specifically, when the main body P21 of the movable part P2 swings in the second mode and viewed along the X axis (first axis), as shown in FIGS. 12 and 13, the main body P21 of the movable part P2 twists the first and second flexible portions P211 and P212 do not overlap. In this embodiment, the frequency of the second periodic signal is close to a different resonance frequency of the movable part P2, thereby improving the flexibility and efficiency of the driving mechanism 200.

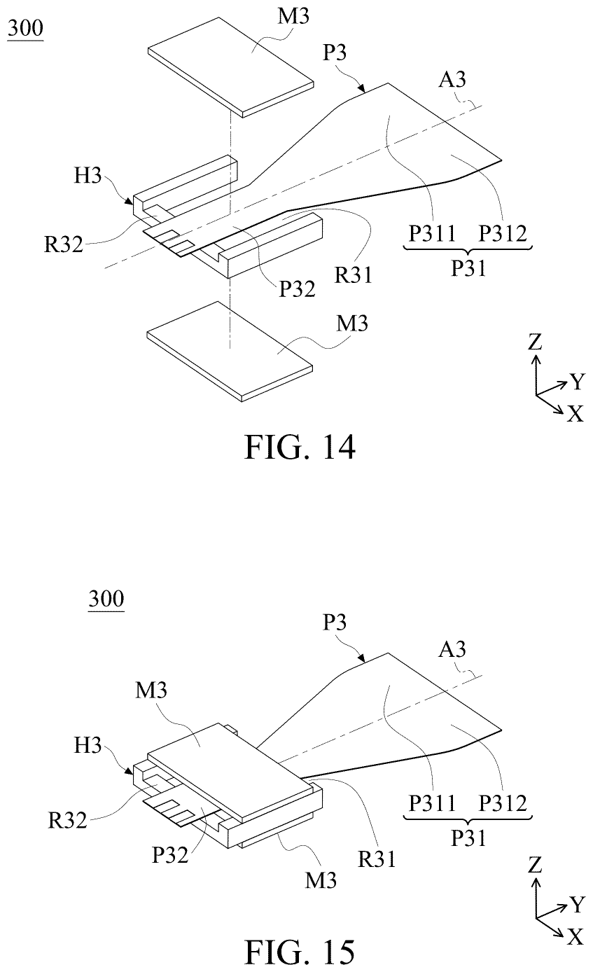

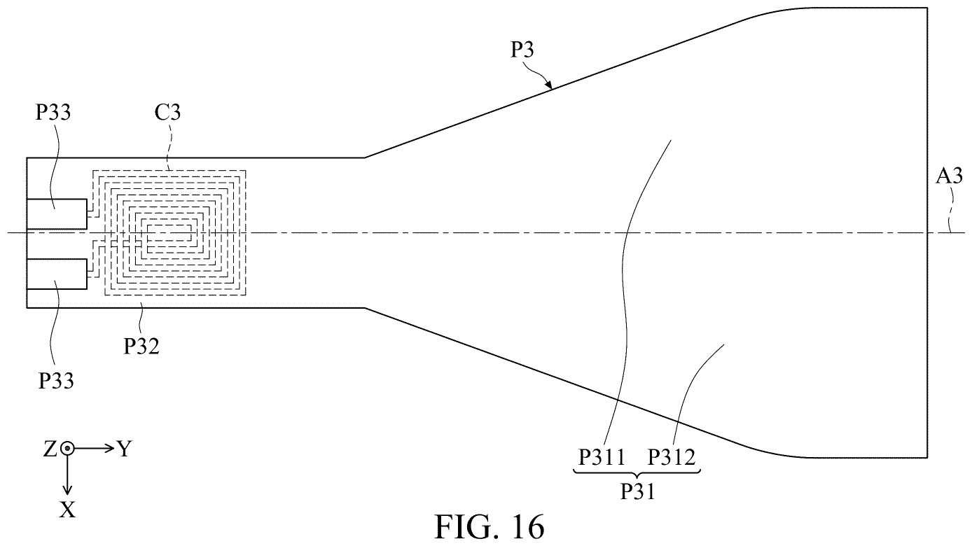

FIG. 14 shows an exploded view of a driving mechanism 300 in accordance with another embodiment of the invention. FIG. 15 is a perspective diagram of the driving mechanism 300 in FIG. 14 after assembly. FIG. 16 is a schematic diagram of the movable part P3 in FIGS. 14 and 15.

Referring to FIGS. 14-16, the driving mechanism 300 may be disposed in an electronic device for driving the movable part P3 (e.g. a fan) to swing and dissipate heat from the electronic device. In this embodiment, the driving mechanism 300 primarily comprises a fixed part H3, a movable part P3 connected to the fixed part H3, two first driving elements M3 disposed on the fixed part H3, and a second driving element C3 disposed on the movable part P3 (FIG. 16). The first driving elements M3 may comprise magnetic material (e.g. a permanent magnet or magnetic permeable material), and the second driving element C3 may be a coil (e.g. a planar coil) formed on or embedded in the movable part P3. The first and second driving elements M3 and C3 constitute a driving assembly for moving the movable part P3 relative to the fixed part H3.

The fixed part H3 has a C-shaped frame that forms a first opening R31 and a second opening R32. The movable part P3 may comprise a metal sheet or a polyimide (PI) sheet that has a flat and thin structure. Specifically, the movable part P3 comprises a main body P31 and a vibrating portion P32 arranged along the central axis A3. The vibrating portion P32 is connected to the main body P31, and the second driving element C3 (e.g. a planar coil) is formed on or embedded in the vibrating portion P32 (FIG. 16).

In this embodiment, the main body P31 of the movable part P3 has a symmetrical structure that includes a first flexible portion P311 and a second flexible portion P312 arranged along the X axis (first axis) which is perpendicular to the central axis A3 of the movable part P3. The first and second flexible portions P311 and P312 are symmetrical with respect to the central axis A3, and the central axis A3 is parallel to the Y axis.

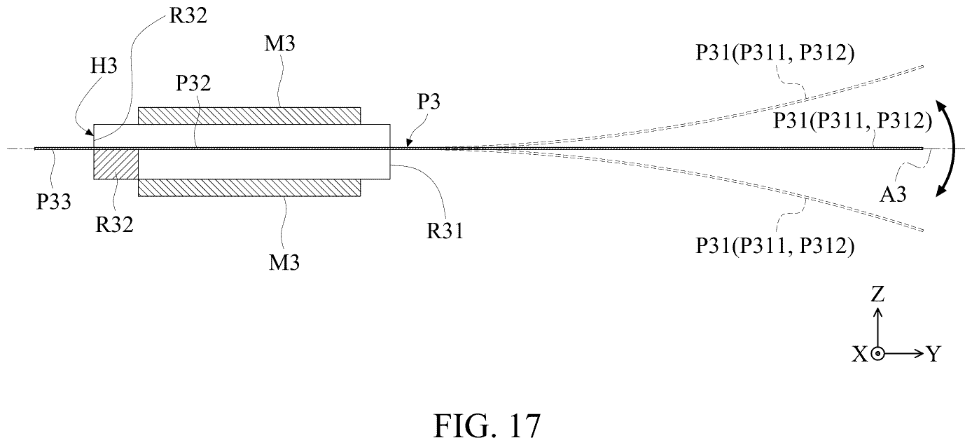

FIG. 17 shows a cross-sectional view of the driving mechanism 300 when a first periodic current signal is applied to the second driving element C3 formed on or embedded in the vibrating portion P32 of the movable part P3.

It can be seen in FIGS. 16 and 17 that the movable part P3 further has two terminal portions P33 electrically connected to the second driving element C3. The terminal portions P33 are adhered to the fixed part H3 and protrude from the fixed part H3 through the second opening R32, wherein the vibrating portion P32 is connected between the terminal portions P33 and the main body P31 of the movable part P3 along the central axis A3.

In this embodiment, the first driving elements M3 are disposed on the upper and lower sides of the fixed part H3. It should be noted that the first driving elements M3 and the second driving element C3 do not overlap when viewed along the central axis A3, and the second driving element C3 is located between the two first driving elements M3 along the Z axis.

Here, the central axis A3 of the movable part P3 extends through the first and second openings R31 and R32 of the fixed part H3. When a first periodic signal is applied to the second driving element C3, the vibrating portion P32 can be driven to vibrate, whereby the main body P31 of the movable part P3 swings in a first mode, thereby generating an air flow to dissipate heat from the electronic device. In this embodiment, the frequency of the first periodic signal is close to one of the resonance frequencies of the movable part P3. Specifically, when the main body P31 of the movable part P3 swings in the first mode and viewed along the X axis (first axis), the first and second flexible portions P311 and P312 substantially overlap (FIG. 17).

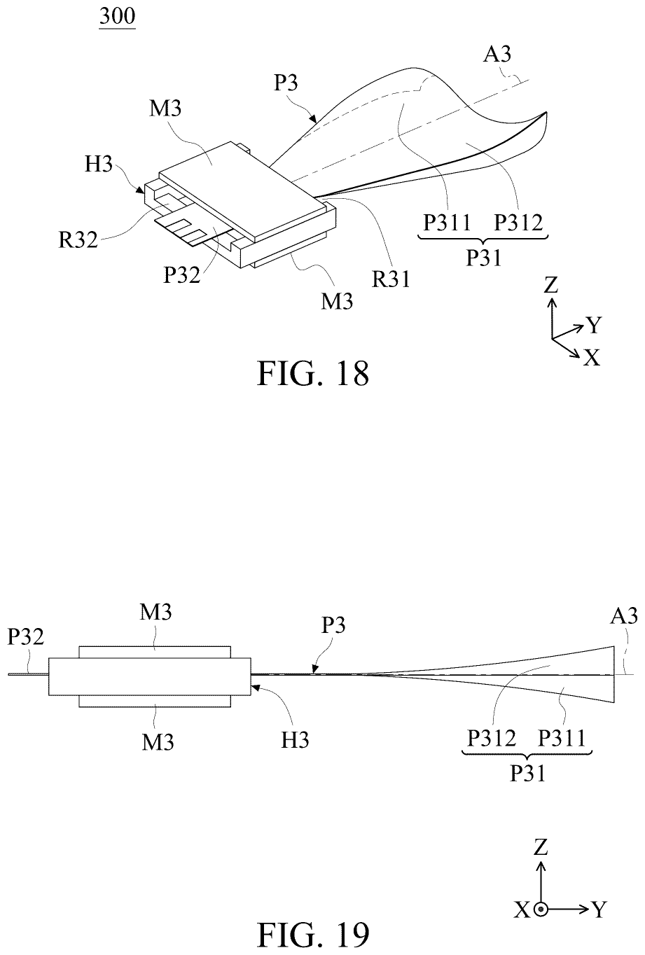

FIG. 18 is a perspective diagram of the driving mechanism 300 when a second periodic current signal is applied to the second driving element C3 formed on or embedded in the vibrating portion P32 of the movable part P3. FIG. 19 shows a side view of the driving mechanism 300 when a second periodic current signal is applied to the second driving element C3 formed on or embedded in the vibrating portion P32 of the movable part P3.

Referring to FIGS. 18 and 19, when a second periodic signal is applied to the second driving element C3 formed on or embedded in the vibrating portion P32 of the movable part P3, the main body P31 of the movable part P3 can be driven to swing in a second mode and generate an air flow to dissipate heat from the electronic device.

Specifically, when the main body P31 of the movable part P3 swings in the second mode and viewed along the X axis (first axis), as shown in FIGS. 18 and 19, the main body P31 of the movable part P3 twists the first and second flexible portions P311 and P312 do not overlap. In this embodiment, the frequency of the second periodic signal is close to a different resonance frequency of the movable part P3, thereby improving the flexibility and efficiency of the driving mechanism 300.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A driving mechanism, comprising:
a fixed part;
a movable part, connected to the fixed part; and
a driving assembly, configured to move the movable part relative to the fixed part.

2. The driving mechanism as claimed in claim 1, wherein the driving assembly includes a first driving element and a second driving element, and the movable part has a main body and a vibrating portion connected to the main body, wherein the first driving element is disposed on a first surface of the vibrating portion, and the second driving element is disposed on the fixed part and located adjacent to the first driving element.

3. The driving mechanism as claimed in claim 2, wherein a first opening and a second opening are formed on opposite sides of the fixed part, the main body protrudes from the fixed part through the first opening, and the vibrating portion is accommodated in the fixed part.

4. The driving mechanism as claimed in claim 3, wherein the movable part does not protrude from the fixed part through the second opening.

5. The driving mechanism as claimed in claim 4, wherein the movable part further has a support portion and a bridge portion, the support portion is affixed to the fixed part, and the bridge portion is connected between the support portion and the main body.

6. The driving mechanism as claimed in claim 5, wherein the support portion and the bridge portion form a T-shaped resilient structure.

7. The driving mechanism as claimed in claim 2, wherein the movable part has a central axis extending through the first and second openings, the main body includes a first flexible portion and a second flexible portion arranged along a first axis that is perpendicular to the central axis, and the first and second flexible portions are symmetrical with respect to the central axis.

8. The driving mechanism as claimed in claim 7, wherein the main body of the movable part moves in a first mode when a first periodic signal is applied to the driving assembly, the main body of the movable part moves in a second mode when a second periodic signal is applied to the driving assembly, and the frequencies of the first and second periodic signals are different.

9. The driving mechanism as claimed in claim 8, wherein the frequency of the first periodic signal is close to one of the resonance frequencies of the movable part, and the frequency of the second periodic signal is close to another one of the resonance frequencies of the movable part.

10. The driving mechanism as claimed in claim 8, wherein the first and second flexible portions overlap when the main body of the movable part moves in the first mode and viewed along the first axis, and the first and second flexible portions do not overlap when the main body of the movable part moves in the second mode and viewed along the first axis.

11. The driving mechanism as claimed in claim 7, wherein the first and second driving elements do not overlap when viewed along the central axis.

12. The driving mechanism as claimed in claim 7, wherein the second driving element comprises an FPC that has an upper portion, a lower portion and a foldable portion connected between the upper and lower portions.

13. The driving mechanism as claimed in claim 12, wherein the upper and lower portions are parallel to each other, the first and second openings are located between the upper and lower portions, and the FPC further has two coils disposed in the upper and lower portions.

14. The driving mechanism as claimed in claim 13, wherein the first driving element is located between the two coils and comprises a permanent magnet or magnetic permeable material.

15. The driving mechanism as claimed in claim 14, wherein the first driving element is formed on the vibrating portion by plating.

16. The driving mechanism as claimed in claim 15, wherein the movable part comprises a thin and flat metal sheet or polyimide (PI) sheet.

17. The driving mechanism as claimed in claim 15, wherein the first driving element has a first portion disposed on a first surface of the vibrating portion, wherein the first surface is parallel to the central axis and the first axis.

18. The driving mechanism as claimed in claim 17, wherein the first driving element further has a second portion disposed on a second surface of the vibrating portion, wherein the first and second surfaces are located on opposite sides of the vibrating portion.

19. The driving mechanism as claimed in claim 18, wherein the first driving element further has a third portion connected between the first and second portions, and the third portion and the vibrating portion do not overlap when viewed in a direction perpendicular to the first surface.

20. The driving mechanism as claimed in claim 15, wherein the vibrating portion is encompassed by the first driving element.
